(19) United States
(12) Patent Application Publication
(10) Pub. No.: US 2009/0230464 A1
(43) Pub. Date: Sep. 17, 2009

(54) SEMICONDUCTOR DEVICE INCLUDING TRENCH GATE TRANSISTOR AND METHOD OF FORMING THE SAME

(75) Inventor: Hiroaki Taketani, Tokyo (JP)

Correspondence Address: YOUNG & THOMPSON, 209 Madison Street, Suite 500, ALEXANDRIA, VA, 22314, US

(73) Assignee: ELPIDA MEMORY,INC., Tokyo (JP)

(21) Appl. No.: 12/403,058

(22) Filed: Mar. 12, 2009

(30) Foreign Application Priority Data
Mar. 14, 2008 (JP) 2008-066678

(51) Int. Cl. H01L 29/78

(52) U.S. Cl. 257/330; 257/E29.255

(57) ABSTRACT

A semiconductor device may include at least one active region that has at least one trench groove. A fin channel region is deposed in the active region and between the at least one trench groove and an isolation region of the semiconductor substrate. The gate insulating film is disposed on inside walls of the at least one trench groove. The gate electrode is disposed on the gate insulating film and in the at least one trench groove. The gate electrode is separated by the gate insulating film from the fin channel region. The source and drain regions are disposed in the active region, and are connected to the fin channel region. The junction of each of the source and drain regions with the semiconductor substrate is deeper than the bottom of the fin channel region.

### BACKGROUND OF THE INVENTION

1. Field of the Invention

The present invention generally relates to a semiconductor device and a method of forming the same. More specifically, the present invention relates to a semiconductor device including a trench gate transistor and a method of forming the same.

Priority is claimed on Japanese Patent Application No. 2008-066678, filed Mar. 14, 2008, the content of which is incorporated herein by reference.

2. Description of the Related Art

In recent years, the dimensions of a transistor have been on the decrease, which may cause remarkable short channel effects of the transistor. The short channel effects cause that the threshold voltage is reduced and the subthreshold characteristic is deteriorated. Some high performance transistors have been attracted, which prevent or suppress the short channel effects. Typical examples of such high performance transistors may include a depletion transistor that uses an SOI (Silicon on Insulator) substrate, and a fin field effect transistor that uses a fin-shaped channel region.

Japanese Unexamined Patent Application, First Publications, Nos. 2007-158269 and 2007-258660 each address a modified fin field effect transistor having a channel region which has a fin shaped SOI structure. The in shaped SOI structure is formed in a trench in an active region of the SOI substrate. The SOI substrate is more expensive than the single crystal silicon substrate that has usually been used. The SOI substrate is not suitable for semiconductor devices such as general DRAMs that need to be manufactured at a low cost.

The depleted fin field effect transistor has a thin silicon layer that performs as a channel region. Reduction in the thickness of the thin silicon layer for the channel region makes it difficult to adjust impurity concentration of the channel region for adjusting the threshold voltage of the transistor. A transistor is desired which allows easy control to the threshold voltage, while the transistor has a thin silicon layer performing as a channel region.

A single transistor DRAM has been investigated, which utilizes that the SOI structure causes the substrate floating effect. The above-identified Japanese Unexamined Patent Application, First Publication, No. 2007-258660 further describes the fin field effect transistor that has channel regions of the side walls of the shallow trench isolation.

The 501 structure is engaged with the above-described problems that the SOI structure causes self-heat generation effects that will reduce the drain current of a transistor that is formed on the SOI structure. The SOI structure needs advanced technologies of processing the thin silicon layer of the SOI such as oxidation process, etching process, and silicidation process.

The fin field effect transistor needs a process for forming a fin channel region on the active region, which results in that it is not easy to form a gate electrode on the fin channel region.

The above-identified Japanese Unexamined Patent Application, First Publication, No. 2007-258660 describes that the fin field effect transistor includes a channel region that includes an SOI channel. The SOI channel is formed on the side walls of the shallow trench isolation, wherein the side walls extend in longitudinal direction of the gate region. The SOI channel contacts with the substrate. Charges generated at the SOI channel will move to the substrate, thereby no appearance of the substrate floating effects.

### SUMMARY

In one embodiment, a semiconductor device may include, but is not limited to, a semiconductor substrate that includes an isolation region and at least one active region, a fin channel region, a gate insulating film, a gate electrode, and source and drain regions. The at least one active region has at least one trench groove. The fin channel region is deposed in the at least one active region. The fin channel region is disposed between the at least one trench groove and the isolation region. The gate insulating film is disposed on inside walls of the at least one trench groove. The gate electrode is disposed on the gate insulating film. The gate electrode is disposed in the at least one trench groove. The gate electrode is separated by the gate insulating film from the fin channel region. The source and drain regions are disposed in the at least one active region. The source and drain regions are connected to the fin channel region. The source and drain regions each have a junction with the semiconductor substrate. The junction is deeper than the bottom of the fin channel region.

In another embodiment, a semiconductor device may include, but is not limited to, a semiconductor substrate that includes an isolation region and at least one active region, a fin channel region, a gate insulating film, a gate electrode, and source and drain regions. The at least one active region has at least one trench groove. The fin channel region is disposed in the at least one active region. The fin channel region is disposed between the at least one trench groove and the isolation region. The bottom of the fin channel region is separated from the semiconductor substrate by a portion of the at least one trench groove. The gate insulating film is disposed on inside walls of the at least one trench groove. The gate electrode is disposed on the-gate insulating film. The gate electrode is disposed in the at least one trench groove. The gate electrode is separated by the gate insulating film from the fin channel region. The source and drain regions are disposed in the at least one active region. The source and drain regions are connected to the fin channel region.

In still another embodiment, a semiconductor device may include, but is not limited to, a semiconductor substrate including an isolation region and at least one active region, a fin channel region, a gate insulating film, a gate electrode, and source and drain regions. The at least one active region has at least one trench groove. The at least one trench groove may include, but is not limited to a first trench portion and a second trench portion positioned under the first trench portion. The second trench portion is connected to the first trench portion. The fin channel region is disposed in the at least one active region. The fin channel region is disposed between the at least one trench groove and the isolation region. The bottom of the fin channel region is separated from the semiconductor substrate by the second trench portion. The fin channel region is defined by the first trench portion, the second trench portion and the isolation region. The gate insulating film is disposed on inside walls of the at least one trench groove. The gate electrode is disposed on the gate insulating film. The gate electrode is disposed in the at least one trench groove. The gate electrode is separated by the gate insulating film from the fin channel region. The source and drain regions are disposed in the at least one active region. The source and drain regions are connected to the fin channel region. The source and drain regions each have a junction with the semiconductor substrate. The junction is deeper than the bottom of the fin channel region.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary plan view illustrating a semiconductor device in accordance with a first preferred embodiment of the present invention;

FIG. 1B is a fragmentary cross sectional elevation view illustrating the semiconductor device, taken along an A-A′ line of FIG. 1A;

FIG. 1C is a fragmentary cross sectional elevation view illustrating the semiconductor device, taken along a B-B′ line of FIG. 1A;

FIG. 2A is a fragmentary cross sectional elevation view, taken along the A-A′ line of FIG. 1A, illustrating a step involved in a method of forming the semiconductor device shown in FIGS. 1A, 1B, and 1C;

FIG. 2B is a fragmentary cross sectional elevation view, taken along the B-B′ line of FIG. 1A, illustrating the same step as in FIG. 2A, involved in the method of forming the semiconductor device shown in FIGS. 1A, 1B, and 1C;

FIG. 3A is a fragmentary cross sectional elevation view, taken along the A-A′ line of FIG. 1A, illustrating a step subsequent to the step of FIGS. 2A and 2B, involved in the method of forming the semiconductor device shown in FIGS. 1A, 1B, and 1C;

FIG. 3B is a fragmentary cross sectional elevation view, taken along the B-B′ line of FIG. 1A, illustrating the same step as in FIG. 3A, involved in the method of forming the semiconductor device shown in FIGS. 1A, 1B, and 1C;

FIG. 4A is a fragmentary cross sectional elevation view, taken along the A-A′ line of FIG. 1A, illustrating a step subsequent to the step of FIGS. 3A and 3B, involved in the method of forming the semiconductor device shown in FIGS. 1A, 1B, and 1C;

FIG. 4B is a fragmentary cross sectional elevation view, taken along the B-B′ line of FIG. 1A, illustrating the same step as in FIG. 4A, involved in the method of forming the semiconductor device shown in FIGS. 1A, 1B, and 1C;

FIG. 5A is a fragmentary cross sectional elevation view, taken along the A-A′ line of FIG. 1A, illustrating a step subsequent to the step of FIGS. 4A and 4B, involved in the method of forming the semiconductor device shown in FIGS. 1A, 1B, and 1C;

FIG. 5B is a fragmentary cross sectional elevation view, taken along the B-B′ line of FIG. 1A, illustrating the same step as in FIG. 5A, involved in the method of forming the semiconductor device shown in FIGS. 1A, 1B, and 1C;

FIG. 6A is a fragmentary cross sectional elevation view, taken along the A-A′ line of FIG. 1A, illustrating a step subsequent to the step of FIGS. 5A and 5B, involved in the method of forming the semiconductor device shown in FIGS. 1A, 1B, and 1C;

FIG. 6B is a fragmentary cross sectional elevation view, taken along the B-B′ line of FIG. 1A, illustrating the same step as in FIG. 6A, involved in the method of forming the semiconductor device shown in FIGS. 1A, 1B, and 1C;

FIG. 7A is a fragmentary cross sectional elevation view, taken along the A-A′ line of FIG. 1A, illustrating a step subsequent to the step of FIGS. 6A and 6B, involved in the method of forming the semiconductor device shown in FIGS. 1A, 1B, and 1C;

FIG. 7B is a fragmentary cross sectional elevation view, taken along the B-B′ line of FIG. 1A, illustrating the same step as in FIG. 7A, involved in the method of forming the semiconductor device shown in FIGS. 1A, 1B, and 1C;

FIG. 8A is a fragmentary cross sectional elevation view, taken along the A-A′ line of FIG. 1A, illustrating a step subsequent to the step of FIGS. 7A and 7B, involved in the method of forming the semiconductor device shown in FIGS. 1A, 1B, and 1C;

FIG. 8B is a fragmentary cross sectional elevation view, taken along the B-B′ line of FIG. 1A, illustrating the same step as in FIG. 8A, involved in the method of forming the semiconductor device shown in FIGS. 1A, 1B, and 1C;

FIG. 9A is a fragmentary cross sectional elevation view, taken along the A-A′ line of FIG. 1A, illustrating a step subsequent to the step of FIGS. 8A and 8B, involved in the method of forming the semiconductor device shown in FIGS. 1A, 1B, and 1C;

FIG. 9B is a fragmentary cross sectional elevation view, taken along the B-B′ line of FIG. 1A, illustrating the same step as in FIG. 9A, involved in the method of forming the semiconductor device shown in FIGS. A, 1B, and 1C;

FIG. 10A is a fragmentary cross sectional elevation view, taken along the A-A′ line of FIG. 1A, illustrating a step subsequent to the step of FIGS. 9A and 9B, involved in the method of forming the semiconductor device shown in FIGS. 1A, 1B, and 1C;

FIG. 10B is a fragmentary cross sectional elevation view, taken along the B-B′ line of FIG. 1A, illustrating the same step as in FIG. 10A, involved in the method of forming the semiconductor device shown in FIGS. 1A, 1B, and 1C;

FIG. 11A is a fragmentary cross sectional elevation view, taken along the A-A′ line of FIG. 1A, illustrating a step subsequent to the step of FIGS. 10A and 10B, involved in the method of forming the semiconductor device shown in FIGS. 1A, 1B, and 1C;

FIG. 11B is a fragmentary cross sectional elevation view, taken along the B-B′ line of FIG. 1A, illustrating the same step as in FIG. 11A, involved in the method of forming the semiconductor device shown in FIGS. 1A, 1B, and 1C;

FIG. 12A is a fragmentary cross sectional elevation view, taken along the A-A′ line of FIG. 1A, illustrating a step subsequent to the step of FIGS. 11A and 11B, involved in the method of forming the semiconductor device shown in FIGS. 1A, 1B, and 1C;

FIG. 12B is a fragmentary cross sectional elevation view, taken along the B-B′ line of FIG. 1A, illustrating the same step as in FIG. 12A, involved in the method of forming the semiconductor device shown in FIGS. 1A, 1B, and 1C;

FIG. 13A is a fragmentary cross sectional elevation view, taken along the A-A′ line of FIG. 1A, illustrating a step subsequent to the step of FIGS. 12A and 12B, involved in the method of forming the semiconductor device shown in FIGS. 1A, 1B, and 1C;

FIG. 13B is a fragmentary cross sectional elevation view, taken along the B-B′ line of FIG. 1A, illustrating the same step as in FIG. 13A, involved in the method of forming the semiconductor device shown in FIGS. 1A, 1B, and 1C;

FIG. 14A is a fragmentary cross sectional elevation view, taken along the A-A′ line of FIG. 1A, illustrating a step subsequent to the step of FIGS. 13A and 13B, involved in the method of forming the semiconductor device shown in FIGS. 1A, 1B, and 1C;

FIG. 14B is a fragmentary cross sectional elevation view, taken along the B-B′ line of FIG. 1A, illustrating the same step as in FIG. 14A, involved in the method of forming the semiconductor device shown in FIGS. 1A, 1B, and 1C;

FIG. 15A is a fragmentary cross sectional elevation view, taken along the A-A′ line of FIG. 1A, illustrating a step subsequent to the step of FIGS. 14A and 14B, involved in the method of forming the semiconductor device shown in FIGS. 1A, 1B, and 1C;

FIG. 15B is a fragmentary cross sectional elevation view, taken along the B-B′ line of FIG. 1A, illustrating the same step as in FIG. 15A, involved in the method of forming the semiconductor device shown in FIGS. 1A, 1B, and 1C;

FIG. 16A is a fragmentary cross sectional elevation view, taken along the A-A′ line of FIG. 1A, illustrating a step subsequent to the step of FIGS. 15A and 15B, involved in the method of forming the semiconductor device shown in FIGS. 1A, 1B, and 1C;

FIG. 16B is a fragmentary cross sectional elevation view, taken along the B-B′ line of FIG. 1A, illustrating the same step as in FIG. 16A, involved in the method of forming the semiconductor device shown in FIGS. 1A, 1B, and 1C;

FIG. 17A is a fragmentary cross sectional elevation view, taken along the A-A′ line of FIG. 1A, illustrating a step subsequent to the step of FIGS. 16A and 16B, involved in the method of forming the semiconductor device shown in FIGS. 1A, 1B, and 1C;

FIG. 17B is a fragmentary cross sectional elevation view, taken along the B-B′ line of FIG. 1A, illustrating the same step as in FIG. 17A, involved in the method of forming the semiconductor device shown in FIGS. 1A, 1B, and 1C:

FIG. 18 is a diagram illustrating the measured variations of the drain current (ID) over the gate voltage (VG) of each of the semiconductor device in accordance with the above-described embodiment of the present invention and the bulk substrate semiconductor device; and

FIG. 19 is a diagram that illustrates simulated transitional characteristics of the substrate floating effect of the semiconductor device in accordance with the embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

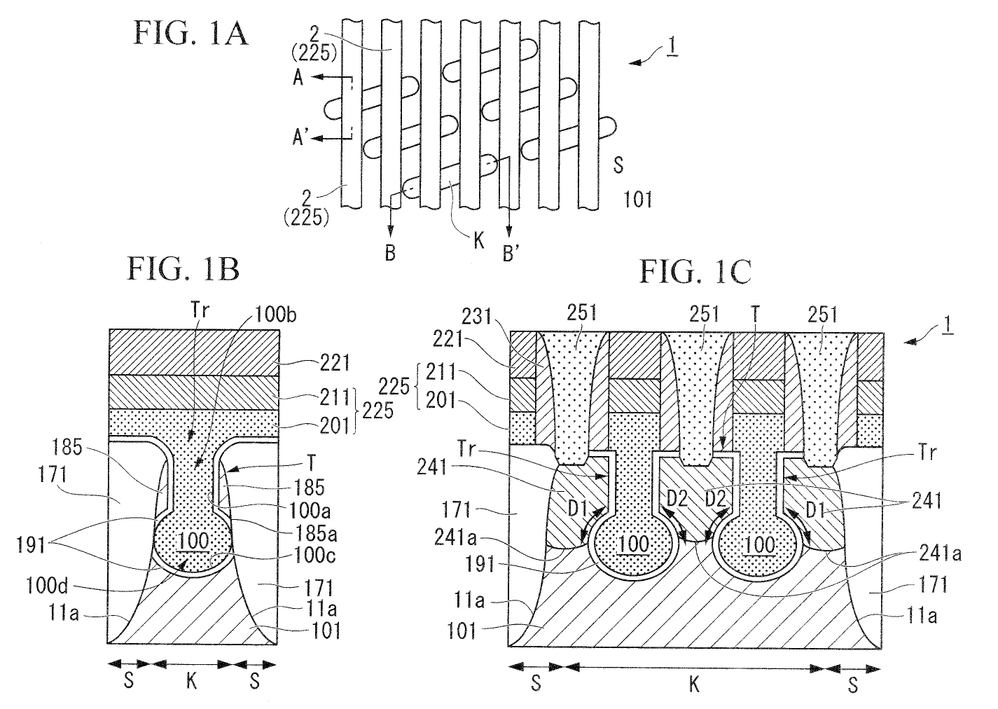

FIG. 1A is a fragmentary plan view illustrating a semiconductor device in accordance with a first preferred embodiment of the present invention. FIG. 1B is a fragmentary cross sectional elevation view illustrating the semiconductor device, taken along an A-A′ line of FIG. 1A. FIG. 1C is a fragmentary cross sectional elevation view illustrating the semiconductor device, taken along a B-B′ line of FIG. 1A.

In accordance with the first preferred embodiment of the present invention, the semiconductor device may be, but is not limited to, a memory transistor for DRAM. The memory transistor may be, but is not limited to, an n-MOS field effect transistor. In FIG. 1A, the A-A′ line is parallel to a direction along which word lines extend, and the B-B′ line is parallel to a direction that is oblique to the A-A′ line. The direction along which the B-B′ line extends is parallel to a longitudinal direction of each active region. FIG. 1B illustrates the fin field effect transistor in the cross sectional view taken along the A-A′ line. FIG. 1C illustrates the fin field effect transistor in the cross sectional view taken along the B-B′ line.

### Semiconductor Device:

With reference to FIGS. 1A, 1B, and 1C, a semiconductor device 1 may include a trench gate MOS transistor Tr that is formed over a semiconductor substrate 101. The trench gate MOS transistor Tr can be applied to a memory cell transistor for DRAM. The trench gate MOS transistor Tr can be an n-MOS field effect transistor.

With reference to FIG. 1A, the semiconductor substrate 101 may include, but is not limited to, an isolation region S and a plurality of active regions K. The isolation region S may be realized by an isolator. Each active region K is surrounded by the isolation region S. Each active region K is separate from other active regions K by the isolation region S. The isolation region S may have a shallow trench isolation structure. Each active region K may typically have a long and thin shape in plan view. The long and thin shape is a modified rectangular shape that has rounded ends. The active regions K may be aligned regularly. In some cases, the plurality of active regions K may form a plurality of alignments of the active regions K. Each alignment includes a sub-plurality of active regions K that are aligned on a straight line that is oblique to the direction along which word lines 2 extend, while the longitudinal direction of each active region K is parallel to the straight line. In some cases, each active region K may extend across and under two adjacent word lines 2 extending in parallel to each other. The two adjacent word lines 2 may be typically aligned at a constant pitch.

With reference to FIGS. 1B and 1C, each active region K has two trenches 100. Each trench 100 is buried with a part of the word line 2. The burying part of the word line 2 may perform as a gate electrode 225.

As described above, the semiconductor substrate 101 may include the active regions K and the isolation region S. The semiconductor substrate 101 may have an isolation groove 11a. The isolation groove 11a may be buried with an isolation film 171. Namely, the isolation region S may have a shallow trench isolation structure. The isolation groove 11a defines a plurality of higher portions T of the semiconductor substrate 1. Each higher portion T is higher than the bottom of the isolation groove 11a. Each higher portion T is surrounded by the isolation film 171.

As described above, each active region K has two trench grooves 100. Each trench groove 100 includes first and second trench portions 100b and 100d. The first trench portion 100b is positioned over the second trench portion 100d. The first trench portion 100b is a shallower portion of the trench groove 100. The second trench portion 100d is a deeper portion of the trench groove 100. The first and second trench portions 100b and 100d are adjacent to each other. The first and second trench portions 100b and 100d communicate with each other. The first and second trench portions 100b and 100d make up the single trench groove 100. The first trench portion 100b has generally vertical walls 100a that extend in a direction that is generally vertical to the semiconductor substrate 101. The first trench portion 100b may have a shape of generally rectangular column. The second trench portion 100d has a generally round shape. The second trench portion 100d has a generally round wall 100c. The second trench portion 100d has the maximum horizontal dimension that is greater than the horizontal direction of the first trench portion 100b. A gate insulating film 191 may be formed on the generally vertical walls 100a and the generally round wall 100c. The gate insulating film 191 may extend along the generally vertical walls 100a and the generally round wall 100c.

Each active region K has a pair of fin channel regions 185. The paired fin channel regions 185 are positioned on opposing sides of the trench groove 100. Each fin channel region 185 is disposed between the gate insulating film 191 on the side walls of the trench groove 100 and the isolation film 171. The lower portion of each fin channel region 185 is tapered between the gate insulating film 191 on the generally round wall 100c and the isolation film 171. Each fin channel region 185 has a bottom edge 185a which is defined by the generally round wall 100c of the second trench portion 100d. The second trench portion 100d with the generally round wall 100c isolates the fin channel region 185 from a lower portion of the active region K of the semiconductor substrate 101. Each fin channel region 185 is defined by the first and second trench portions 101b and 101d and the isolation film 171.

Each active region K also includes source and drain regions 241 in its shallower portion. The source and drain regions 241 have bottoms which are shallower than the bottoms of the second trench portion 100d. One of the source and drain regions 241 is disposed between the first trench portions 101b of the two adjacent trench grooves 100, and the other is disposed between the first trench portion 101b and the isolation film 171. The source and drain regions 241 are connected to the fin channel regions 185.

The first trench portion 101b has the shape of generally rectangle column, which is defined by a first pair of generally vertical walls 100a and a second pair of generally vertical walls 100a. The first-paired generally vertical walls 100a are parallel to each other. The first-paired generally vertical walls 100a are distanced from each other in the direction of A-A′ line. The first-paired generally vertical walls 100a are adjacent to the pair of fin channel regions 185. The second-paired generally vertical walls 100a are parallel to each other. The second-paired generally vertical walls 100a are distanced from each other in the direction of B-B′ line. The direction of B-B′ line is oblique to the direction of A-A′ line. The first-paired generally vertical walls 100a are adjacent to the source and drain regions 241. The first trench portion 101b of the generally rectangle column shape is surrounded by the pair of fin channel regions 185 and the source and drain regions 241. Each fin channel region 185 connects between the source and drain regions 241.

A conductive layer 201 that can be realized by, but not limited to, a polysilicon layer 201, is disposed over the isolation film 171 and the active regions K. The conductive layer 201 such as the polysilicon layer 201 is also disposed on the gate insulating film 191, so that the conductive layer 201 fills up the trench grooves 100. A low resistive film 211 is disposed over the conductive layer 201 such as the polysilicon layer 201. A cap insulating film 221 is disposed over the low resistive film 211. The combination of the conductive layer 201 such as the polysilicon layer 201 with the low resistive film 211 makes up a gate electrode 225. The gate insulating film 191 separates the gate electrode 225 from the fin channel regions 185.

As described above, each active region K is surrounded by the isolation film 171. In the cross sectioned view of FIG. 1C, the active region K is disposed between the isolation films 171. Each active region K has two trench grooves 100. Also, each active region K includes the source and drain regions 241 as described above. The source and drain regions 241 are usually realized by impurity-diffusion layers. The gate insulating film 191 separates the gate electrode 225 from the source and drain regions 241. Each fin channel region 185 connects between the source aid drain regions 241, so that the fin channel region 185 performs as a channel between the source and drain regions 241. The gate electrode 225 has a part that of the generally rectangle column shape, which is presented in the first trench portion 101b of the generally rectangle column shape. The gate electrode 225 is separate by the gate insulating film from the fin channel regions 185 and the source and drain regions 241. The paired fin channel regions 185 are positioned on first-opposing sides of the first trench portion 101b of the generally rectangle column shape, while the source and drain regions 241 are positioned on the second-opposing sides thereof.

The source and drain regions 241 each have a junction with the semiconductor substrate 101. Namely, the junction is formed at the boundary between the source and drain regions 241 and the semiconductor substrate 101. The boundary or the junction between the source and drain regions 241 and the semiconductor substrate 101 is deeper than the bottom of each fin channel region 185, so that each fin channel region 185 is separate from the semiconductor substrate 101 by the source and drain regions 241. Also, each fin channel region 185 is surrounded by the gate insulating film 191, the isolation film 171, and the source and drain regions 241. Each fin channel region 185 is electrically connected to the source and drain regions 241.

The semiconductor device 1 may additionally include contact plugs 251 that are connected to the source and drain regions 241. The contact plugs 251 are positioned over the source and drain regions 241. The contact plugs 251 extend upwardly from the source and drain regions 241. Side wall insulating films 231 are disposed along the side walls of each stack of the gate electrode 225 and the cap insulating film 221. The side wall insulating films 231 separate the contact plugs 251 from the gate electrodes 225. In some cases, the side wall insulating films 231 may be realized by, but not limited to, silicon nitride films.

The semiconductor device 1 may includes but is not limited to, a trench gate MOS transistor Tr. The trench gate MOS transistor Tr is disposed in the active region K of the semiconductor substrate 10. Each active region K is isolated by the isolation film 171. The trench gate MOS transistor Tr may include, but is not limited to, the gate electrode 225, the source and drain regions 241 and the fin channel regions 185. The gate electrode 225 is disposed in the trench groove 100 of the active region K. The gate electrode 225 is separated by the gate insulating film 191 from the fin channel regions 185. The gate electrode 225 is separated by the gate insulating film 191 from the source and drain regions 241. The fin channel regions 185 connects the source and drain regions 241. The fin channel regions 185 are separated by the source and drain regions 241 from the semiconductor substrate 101.

The gate electrode 225 in the trench groove 100 performs as a trench gate that drives the transistor Tr. Each active region K includes the fin channel regions 185 that are disposed between the gate insulating film 191 and the isolation film 171 in the isolation region S. The junction 241a between the source and drain regions 241 and the semiconductor substrate 101 is deeper than the bottom edge 185a of the fin channel region 185. The second trench portion 100d has the horizontal dimension that is greater than that of the first trench portion 100b, so that the fin channel regions 185 are separated by the second trench portion 100d from the semiconductor substrate 101.

### Method of Forming A Semiconductor Device:

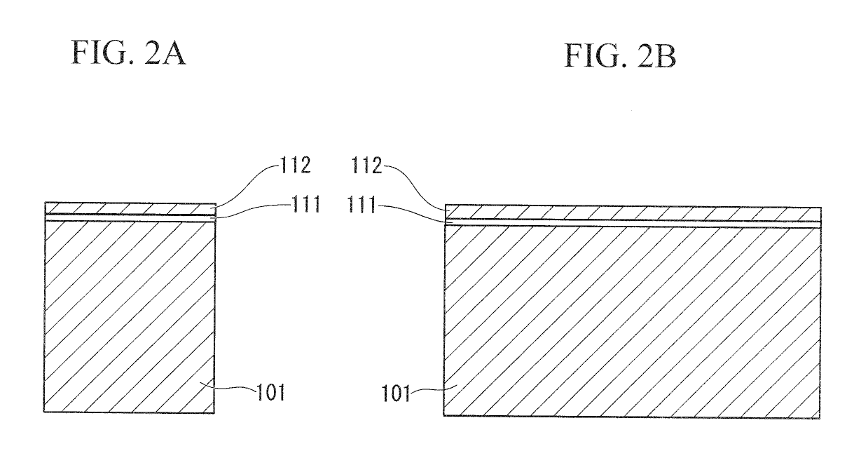

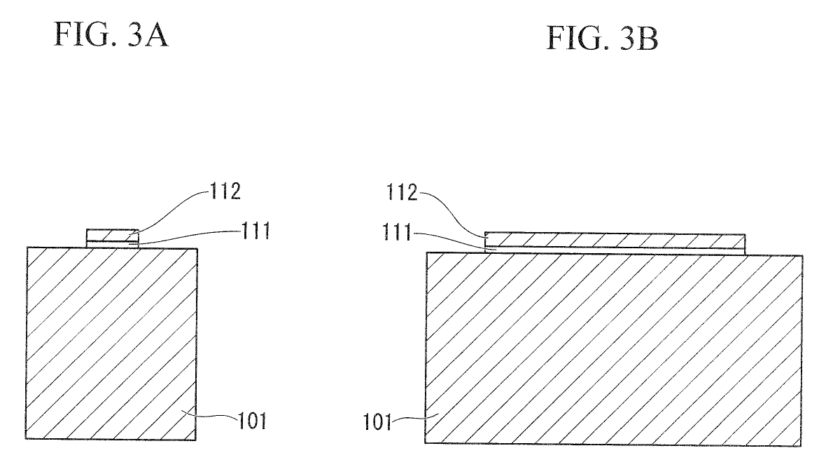

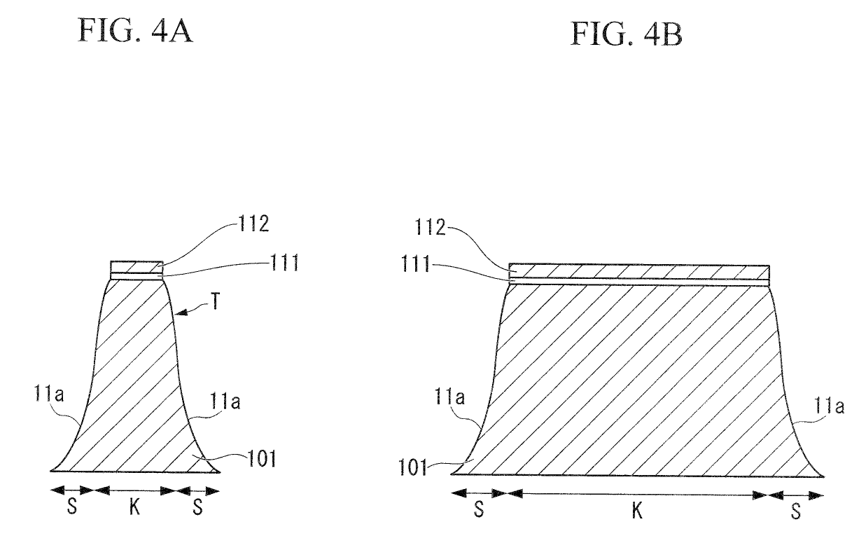

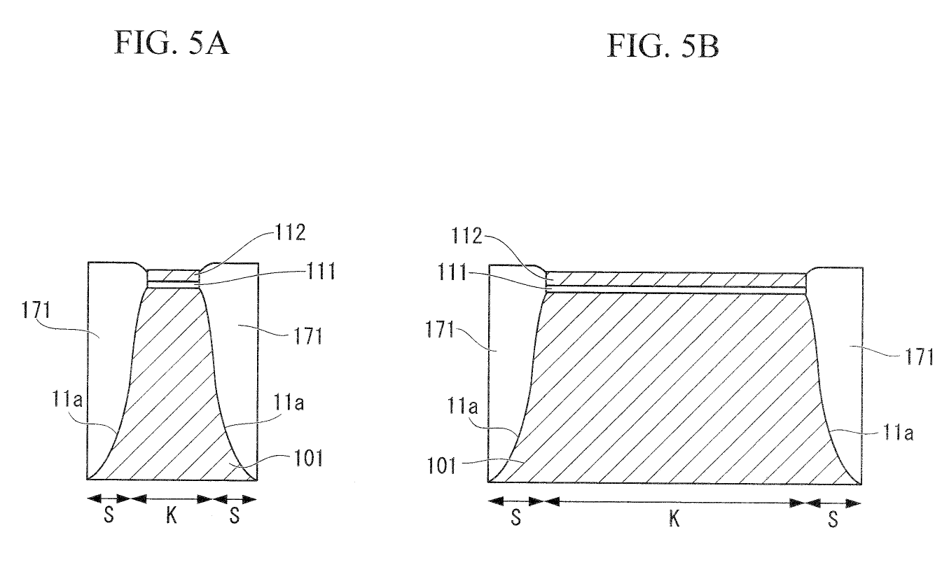

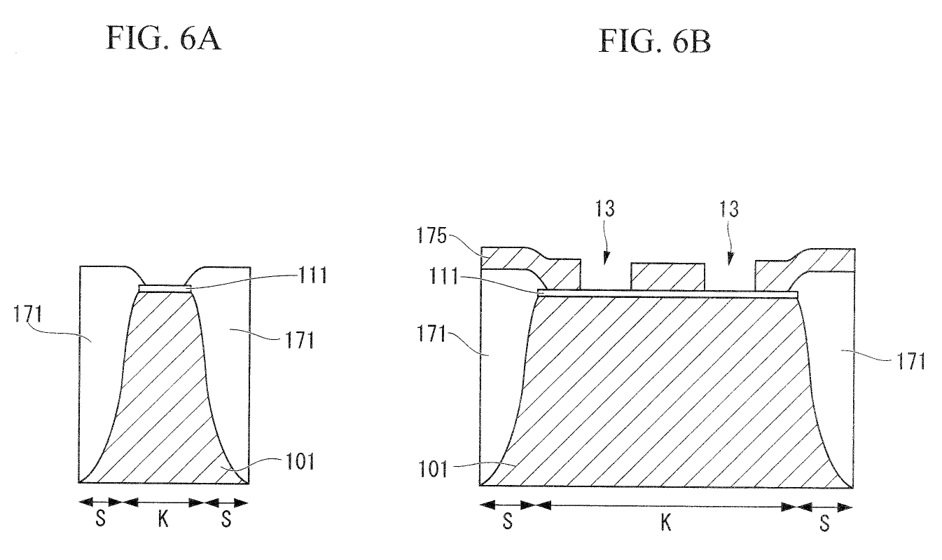

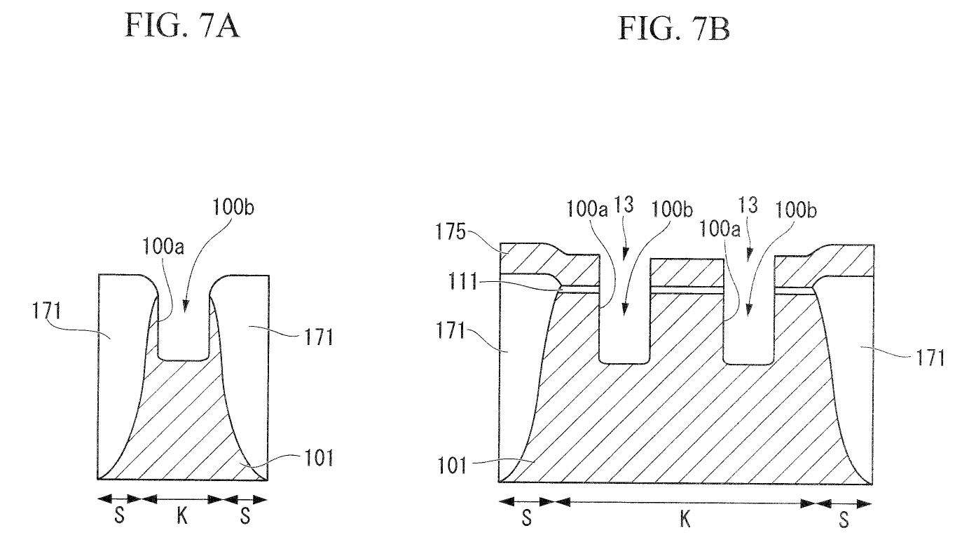

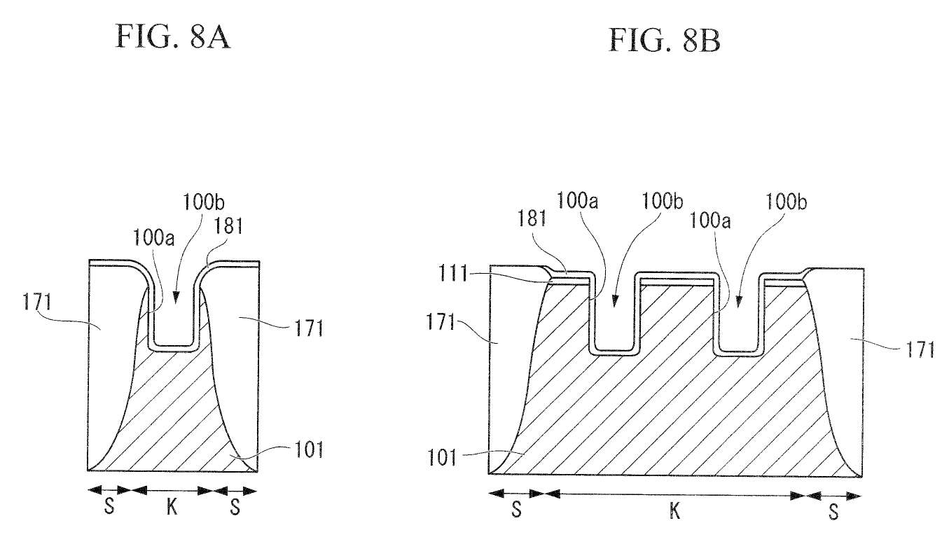

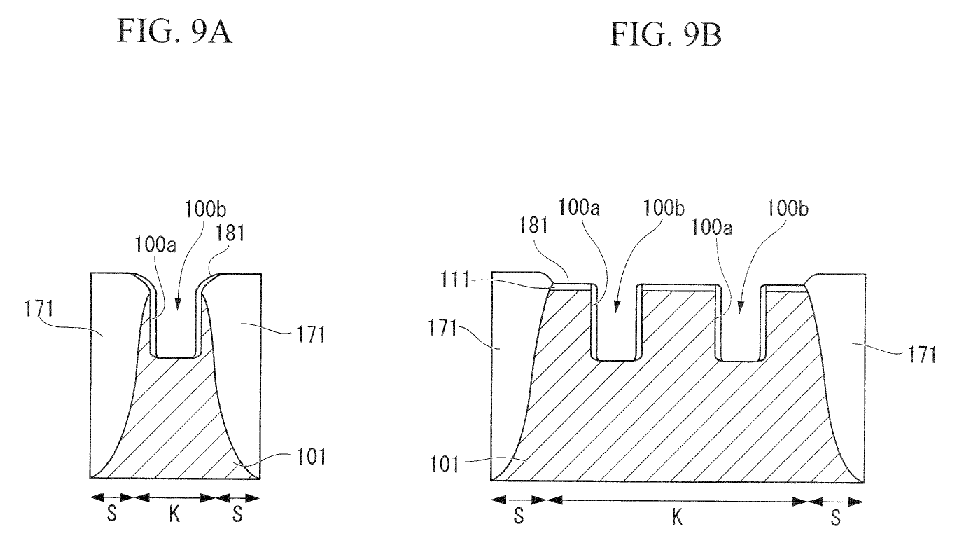

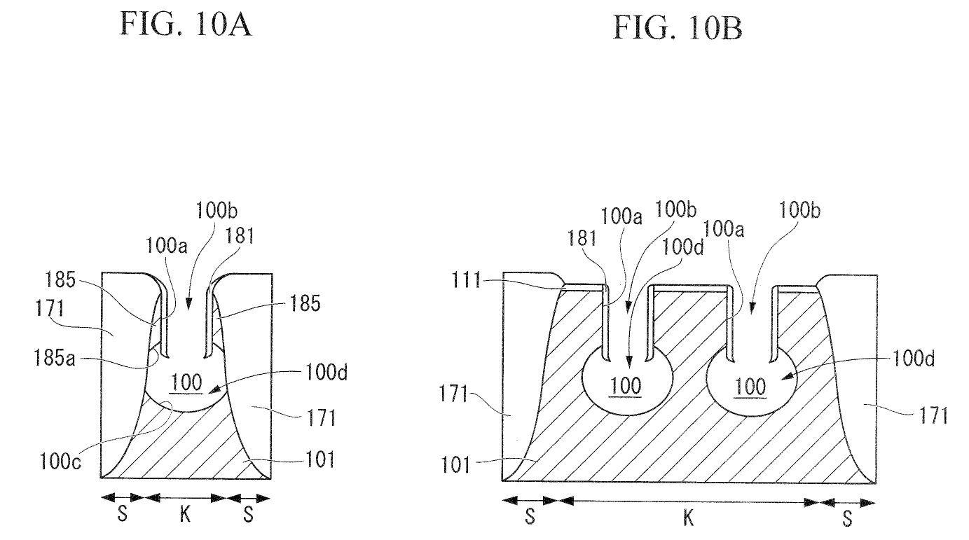

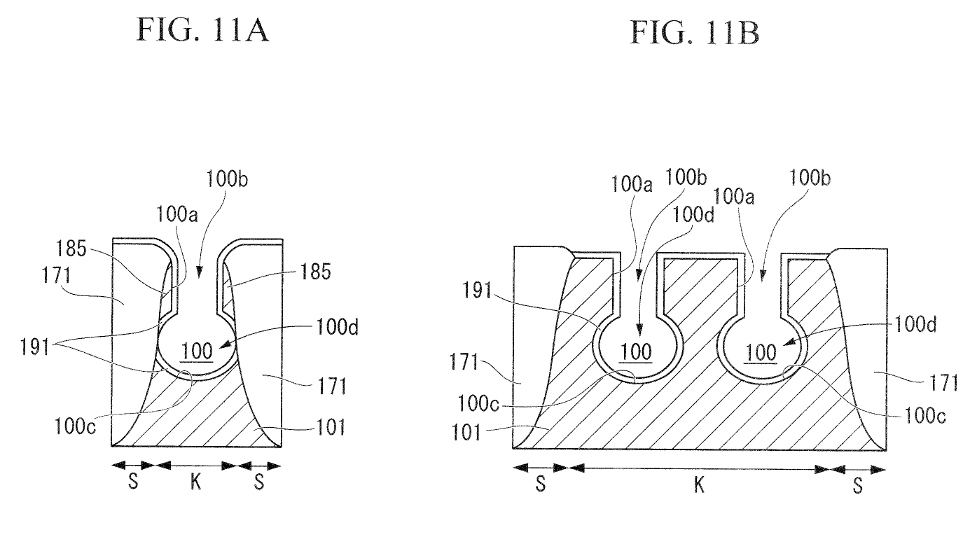

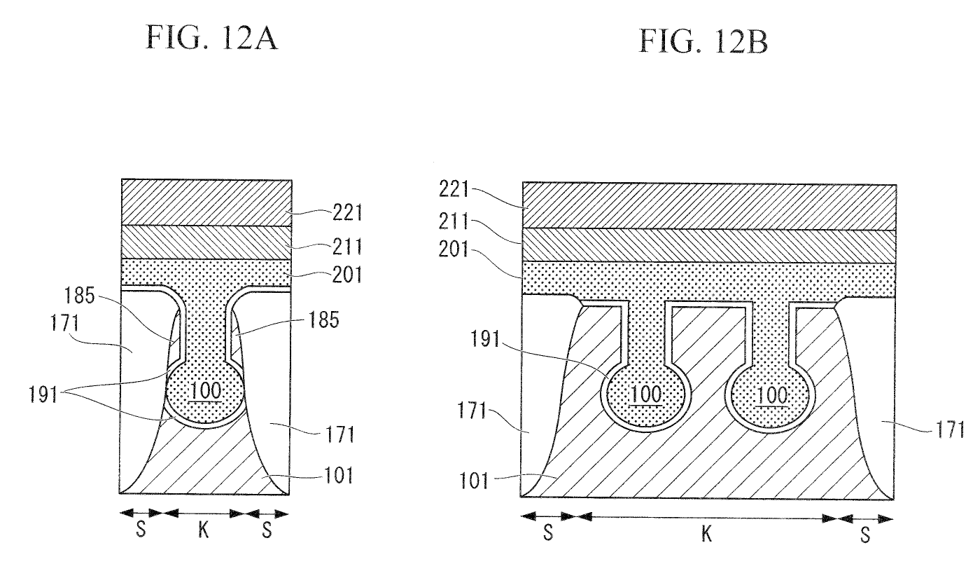

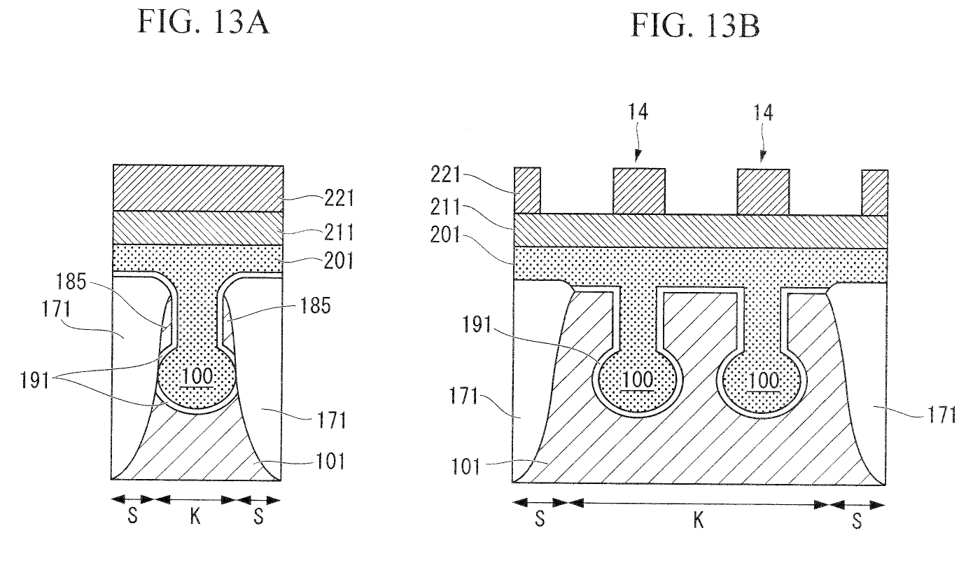

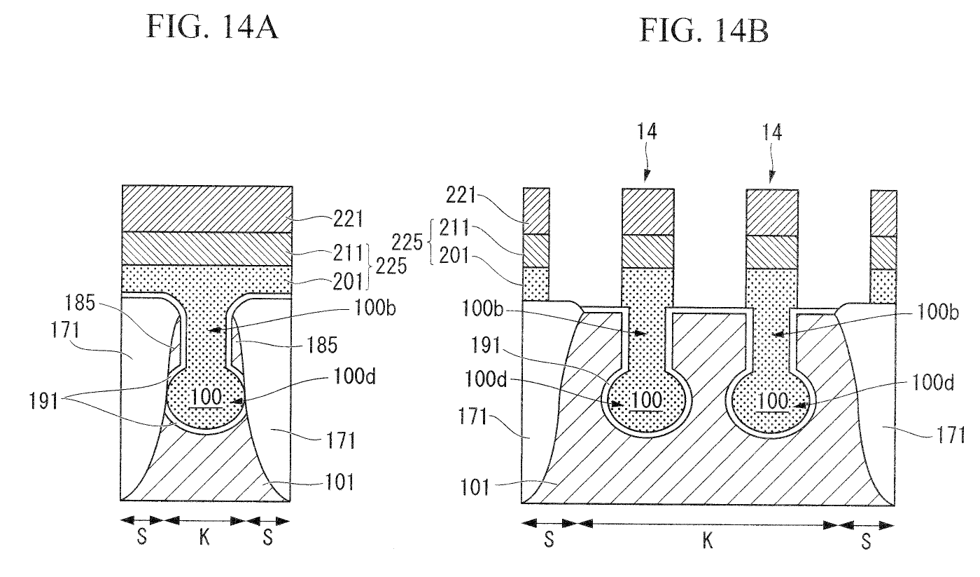

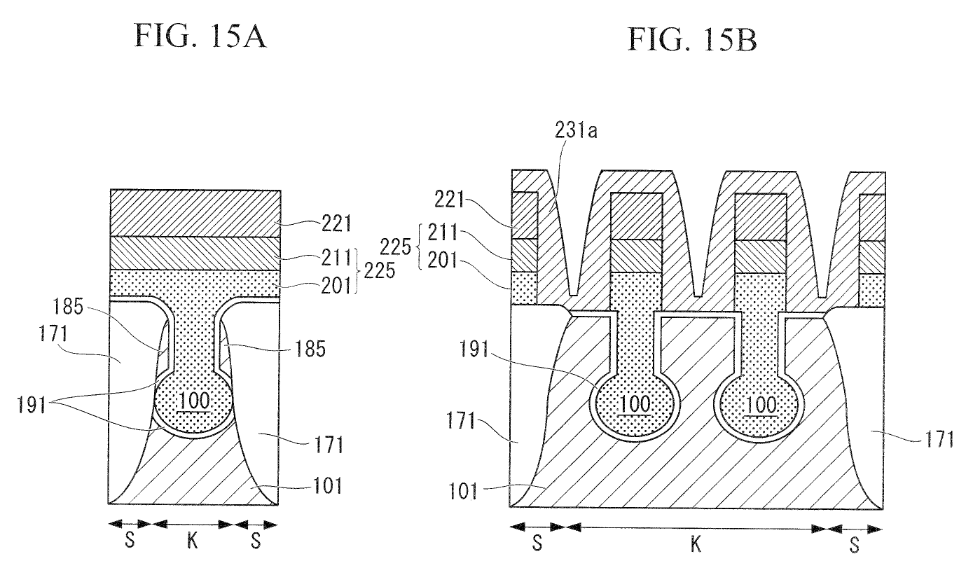

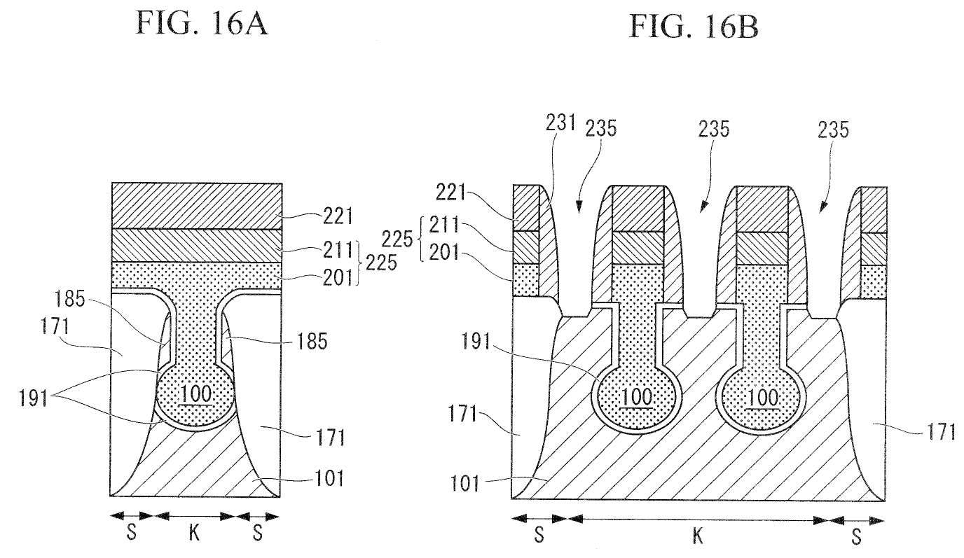

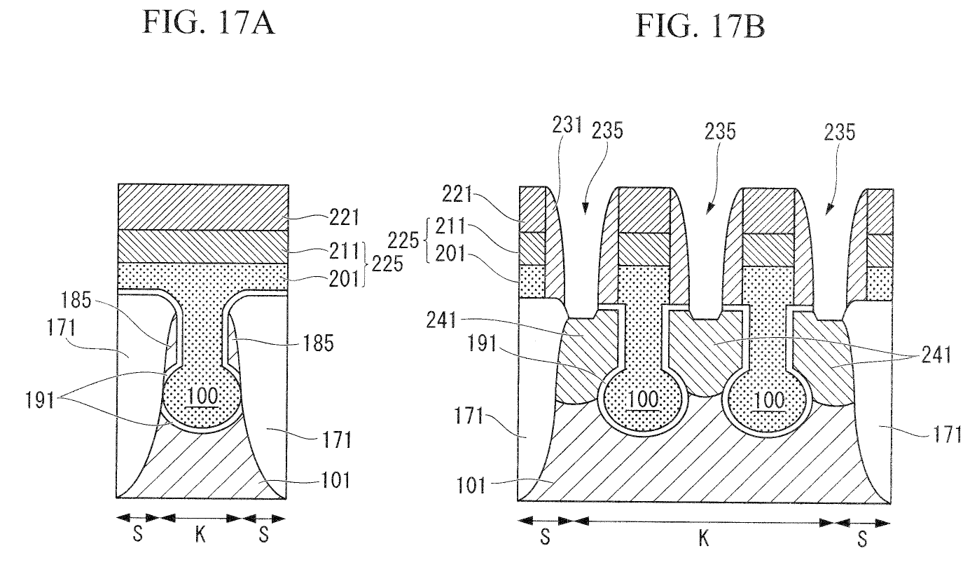

The semiconductor device 1 has been described above in details with reference to FIGS. 1A, 1B and 1C. The followings will address a method of forming the semiconductor device 1 with reference to FIGS. 2A through 17B and again reference to FIGS. 1A, 1B and 1C. FIG. 2A is a fragmentary cross sectional elevation view, taken along the A-A′ line of FIG. 1A, illustrating a step involved in a method of forming the semiconductor device shown in FIGS. 1A, 1B, and 1C. FIG. 2B is a fragmentary cross sectional elevation view, taken along the B-B′ line of FIG. 1A, illustrating the same step as in FIG. 2A, involved in the method of forming the semiconductor device shown in FIGS. 1A, 1B, and 1C. FIG. 3A is a fragmentary cross sectional elevation view, taken along the A-A′ line of FIG. 1A, illustrating a step subsequent to the step of FIGS. 2A and 2B, involved in the method of forming the semiconductor device shown in FIGS. 1A, 1B, and 1C. FIG. 3B is a fragmentary cross sectional elevation view, taken along the B-B′ line of FIG. 1A, illustrating the same step as in FIG. 3A, involved in the method of forming the semiconductor device shown in FIGS. 1A, 1B, and 1C. FIG. 4A is a fragmentary cross sectional elevation view, taken along the A-A′ line of FIG. 1A, illustrating a step subsequent to the step of FIGS. 3A and 3B, involved in the method of forming the semiconductor device shown in FIGS. 1A, 1B, and 1C. FIG. 4B is a fragmentary cross sectional elevation view, taken along the B-B′ line of FIG. 1A, illustrating the same step as in FIG. 4A, involved in the method of forming the semiconductor device shown in FIGS. 1A, 1B, and 1C. FIG. 5A is a fragmentary cross sectional elevation view, taken along the A-A′ line of FIG. 1A, illustrating a step subsequent to the step of FIGS. 4A and 4B, involved in the method of forming the semiconductor device shown in FIGS. 1A, 1B, and 1C. FIG. 5B is a fragmentary cross sectional elevation view, taken along the B-B′ line of FIG. 1A, illustrating the same step as in FIG. 5A, involved in the method of forming the semiconductor device shown in FIGS. 1A, 1B, and 1C. FIG. 6A is a fragmentary cross sectional elevation view, taken along the A-A′ line of FIG. 1A, illustrating a step subsequent to the step of FIGS. 5A and 5B, involved in the method of forming the semiconductor device shown in FIGS. 1A, 1B, and 1C. FIG. 6B is a fragmentary cross sectional elevation view, taken along the B-B′ line of FIG. 1A, illustrating the same step as in FIG. 6A, involved in the method of forming the semiconductor device shown in FIGS. 1A, 1B, and 1C. FIG. 7A is a fragmentary cross sectional elevation view, taken along the A-A′ line of FIG. 1A, illustrating a step subsequent to the step of FIGS. 6A and 6B, involved in the method of forming the semiconductor device shown in FIGS. 1A, 1B, and 1C. FIG. 7B is a fragmentary cross sectional elevation view, taken along the B-B′ line of FIG. 1A, illustrating the same step as in FIG. 7A, involved in the method of forming the semiconductor device shown in FIGS. 1A, 1B, and 1C. FIG. 8A is a fragmentary cross sectional elevation views taken along the A-A′ line of FIG. 1A, illustrating a step subsequent to the step of FIGS. 7A and 7B, involved in the method of forming the semiconductor device shown in FIGS. 1A, 1B, and 1C. FIG. 8B is a fragmentary cross sectional elevation view, taken along the B-B′ line of FIG. 1A, illustrating the same step as in FIG. 8A, involved in the method of forming the semiconductor device shown in FIGS. 1A, 1B, and 1C. FIG. 9A is a fragmentary cross sectional elevation view, taken along the A-A′ line of FIG. 1A, illustrating a step subsequent to the step of FIGS. 8A and 8B, involved in the method of forming the semiconductor device shown in FIGS. 1A, 1B, and 1C. FIG. 9B is a fragmentary cross sectional elevation view, taken along the B-B′ line of FIG. 1A, illustrating the same step as in FIG. 9A, involved in the method of forming the semiconductor device shown in FIGS. 1A, 1B, and 1C. FIG. 10A is a fragmentary cross sectional elevation view, taken along the A-A′ line of FIG. 1A, illustrating a step subsequent to the step of FIGS. 9A and 9B, involved in the method of forming the semiconductor device shown in FIGS. 1A, 1B, and 1C. FIG. 10B is a fragmentary cross sectional elevation view, taken along the B-B′ line of FIG. 1A, illustrating the same step as in FIG. 10A, involved in the method of forming the semiconductor device shown in FIGS. 1A, 1B, and 1C. FIG. 11A is a fragmentary cross sectional elevation view, taken along the A-A′ line of FIG. 1A, illustrating a step subsequent to the step of FIGS. 10A and 10B, involved in the method of forming the semiconductor device shown in FIGS. 1A, 1B, and 1C. FIG. 11B is a fragmentary cross sectional elevation view, taken along the B-B′ line of FIG. 1A, illustrating, the same step as in FIG. 11A, involved in the method of forming the semiconductor device shown in FIGS. 1A, 1B, and 1C. FIG. 12A is a fragmentary cross sectional elevation view, taken along the A-A′ line of FIG. 1A, illustrating a step subsequent to the step of FIGS. 11A and 11B, involved in the method of forming the semiconductor device shown in FIGS. 1A, 1B, and 1C. FIG. 12B is a fragmentary cross sectional elevation view, taken along the B-B′ line of FIG. 1A, illustrating the same step as in FIG. 12A, involved in the method of forming the semiconductor device shown in FIGS. 1A, 1B, and 1C. FIG. 13A is a fragmentary cross sectional elevation view, taken along the A-A′ line of FIG. 1A, illustrating a step subsequent to the step of FIGS. 12A and 12B, involved in the method of forming the semiconductor device shown in FIGS. 1A, 1B, and 1C. FIG. 13B is a fragmentary cross sectional elevation view, taken along the B-B′ line of FIG. 1A, illustrating the same step as in FIG. 13A, involved in the method of forming the semiconductor device shown in FIGS. 1A, 1B, and 1C. FIG. 14A is a fragmentary cross sectional elevation view, taken along the A-A: line of FIG. 1A, illustrating a step subsequent to the step of FIGS. 13A and 13B, involved in the method of forming the semiconductor device shown in FIGS. 1A, 1B, and 1C. FIG. 14B is a fragmentary cross sectional elevation view, taken along the B-B′ line of FIG. 1A, illustrating the same step as in FIG. 14A, involved in the method of forming the semiconductor device shown in FIGS. 1A, 1B, and 1C. FIG. 15A is a fragmentary cross sectional elevation views, taken along the A-A′ line of FIG. 1A, illustrating a step subsequent to the step of FIGS. 14A and 14B, involved in the method of forming the semiconductor device shown in FIGS. 1A, 1B, and 1C. FIG. 15B is a fragmentary cross sectional elevation view, taken along the B-B′ line of FIG. 1A, illustrating the same step as in FIG. 15A, involved in the method of forming the semiconductor device she in FIGS. 1A, 1B, and 1C. FIG. 16A is a fragmentary cross sectional elevation view, taken along the A-A′ line of FIG. 1A, illustrating a step subsequent to the step of FIGS. 15A and 15B, involved in the method of forming the semiconductor device shown in FIGS. 1A, 1B, and 1C. FIG. 16B is a fragmentary cross sectional elevation view, taken along the B-B′ line of FIG. 1A, illustrating the same step as in FIG. 16A, involved in the method of forming the semiconductor device shown in FIGS. 1A, 1B, and 1C. FIG. 17A is a fragmentary cross sectional elevation view, taken along the A-A′ line of FIG. 1A, illustrating a step subsequent to the step of FIGS. 16A and 16B, involved in the method of forming the semiconductor device shown in FIGS. 1A, 1B, and 1C. FIG. 17B is a fragmentary cross sectional elevation view, taken along the B-B′ line of FIG. 1A, illustrating the same step as in FIG. 17A, involved in the method of forming the semiconductor device shown in FIGS. 1A, 1B, and 1C.

The method of forming the semiconductor device may include, but us not limited to, a process for forming an isolation region; a process for forming a trench groove, a process for forming a gate electrode, and a process for forming source and drain regions.

### (Process for Forming an Isolation Region)

A semiconductor substrate 101 is prepared. An isolation region S is defined, while a plurality of active regions K is defined. Each active region K is surrounded by the isolation region S.

With reference to FIGS. 2A and 2B, a semiconductor substrate 101 is prepared. In some cases, the semiconductor substrate 101 may be, but is not limited to, a p-type silicon substrate A silicon oxide film 111 is formed on the surface of the semiconductor substrate 101. In some case, a thermal oxidation process can be used to form the silicon oxide film 111 on the surface of the semiconductor substrate 101. In some cases, the silicon oxide film 111 may have a thickness of, but not limited to, 10 nanometers. A silicon nitride film 112 is formed on the silicon oxide film 111. In some case, a low pressure chemical vapor deposition process can be used to form the silicon nitride film 112 on the silicon oxide film 111. In some cases, the silicon nitride film 11 may have a thickness of, but not limited to, 150 nanometers.

With reference to FIGS. 3A and 3B, a lithography process is carried out to form a resist pattern on the silicon nitride film 112. A dry etching process is carried out by using the resist pattern as a mask to etch the silicon nitride film 112 and the silicon oxide film 111 selectively and anisotropically. The used resist pattern is then removed.

With reference to FIGS. 4A and 4B, an isolation groove 11a is formed in the semiconductor substrate 101. For example, an etching process is carried out using the silicon nitride films 112 as a mask to selectively etch the semiconductor substrate 101, thereby forming the isolation groove 11a in the semiconductor substrate 101. In some cases, the etching depth may be, but is not limited to, 200 nanometers. The isolation groove 11a defines the isolation region S. In other words, the isolation groove 11a shares the isolation region S. The isolation groove 11a defines a plurality of higher portions T of the semiconductor substrate 1. Each higher portion T is higher than the bottom of the isolation groove 11a. Each higher portion T is surrounded by the isolation film 171 Each higher portion T defines an active region K. In other words, the higher portion T shares the active region K.

With reference to FIGS. 5A and 5B, an insulating film is formed entirely over the semiconductor substrate 101, so that the insulating film fills up the isolation groove 11a and covers the silicon nitride films 112. In some cases, the insulating film may be, but is not limited to, an oxide film. A high density plasma chemical vapor deposition can be used to form the insulating film entirely over the semiconductor substrate 101. In some cases, the insulating film may have a thickness of, but not limited to, 400 nanometers.

The insulating film is then polished using the silicon nitride films 112 as stoppers, thereby forming an isolation film 171 in the isolation groove 11a. The isolation film 171 fills up the isolation groove 11a and does not cover the silicon nitride films 112. Typically, a chemical mechanical polishing process can be used to polish the insulating film. The isolation film 171 extends in the isolation region S. The isolation film 171 shares in the isolation region S.

### (Process for Forming a Trench Groove)

Trench grooves 100 are selectively formed in each active region K, while fin channel regions 185 are defined between the trench grooves 100 and the isolation film 171.

With reference to FIGS. 6A and 6B, the silicon nitride films 112 are removed from the semiconductor substrate 101. A hot phosphoric acid can be used to remove the silicon nitride films 112. A silicon nitride film 175 is formed entirely over the semiconductor substrate 101. A low pressure mechanical vapor deposition process can be used to form the silicon nitride film 175 entirely over the semiconductor substrate 101. In some cases, the silicon nitride film 175 may have a thickness of, but not limited to, 100 nanometers. A lithography process is carried out to form a resist pattern on the silicon nitride film 175. A dry etching process is carried out by using the resist pattern as a mask to etch the silicon nitride film 175 selectively and anisotropically, thereby forming gate trench patterns 13 in the silicon nitride film 175. The silicon oxide film is partially shown through the gate trench patterns 13 of the silicon nitride film 175. The used resist pattern is then removed.

With reference to FIGS. 7A and 7B, the silicon oxide film 111 is selectively removed so that the surface of the semiconductor substrate 101 is shown through the gate trench patterns 13 of the silicon nitride film 175. Typically, the silicon nitride film 175 can be used as an etching mask to selectively etch the silicon oxide film 111 so that the surface of the semiconductor substrate 101 is shown through the gate trench patterns 13 of the silicon nitride film 175. The etching depth may be, but is not limited to, 10 nanometers. The etching process for selectively etching the silicon oxide film 111 can be carried out by using an etching gas. A typical example of the etching gas may be, but is not limited to, a mixture gas of CF₄ and Ar.

First trench portions 100b with generally vertical walls 100a are selectively formed in each active region K. A further etching process can be used by using the silicon oxide film 111 as a mask to selectively etch the active regions K of the semiconductor substrate 101, thereby forming a part of the first trench portions 100b with generally vertical walls 100a in each active region K. The further etching process may have an etching rate of silicon to silicon oxide. The further etching process may be carried out by using a mixture gas that has a high etching rate of silicon to silicon oxide, so as to selectively etch the silicon substrate 101, without etching the silicon oxide film 111. A typical example of the mixture gas may include, but not limited to, Cl₂ (chlorine), HBr (hydrogen bromide), and O₂ (oxygen).

With reference to FIGS. 8A and 8B, the silicon nitride films 175 are removed from the semiconductor substrate 101. A hot phosphoric acid can be used to remove the silicon nitride films 175 from the semiconductor substrate 101. A thermal oxidation process is carried out to form a silicon oxide film 181 on the silicon oxide film 111 and on the inner walls of the first trench portions 100b, wherein the inner walls of the first trench portions 100b include the generally vertical walls 100a.

With reference to FIGS. 9A and 9B, an anisotropic etching process is carried out to selectively remove the silicon oxide film 181 from the silicon oxide film 111 and from the bottom walls of the first trench portions 100b, resulting in that the silicon oxide film 181 remains on the generally vertical walls 100a. In some cases, the anisotropic etching process can be carried out by using an etching gas, which may typically be, but is not limited to, a mixture of gases such as CF₄ and Ar.

With reference to FIGS. 10A and 10B, an isotropic etching process is carried out to form second trench portions 100d in the semiconductor substrate 101. The isotropic etching process does isotropically etch the bottom of the first trench portion 100d. The second trench portion 100d has a generally round shape. The second trench portion 100d has a generally round wall 100c. The second trench portions 100d communicate with the first trench portions 100b. The second trench portion 100d has the maximum horizontal dimension that is greater than the horizontal direction of the first trench portion 100b. The first and second trench portions 100b and 100d make up the trench groove 100. The second trench portion 100d is a deeper portion of the trench groove 100. In some cases, the isotropic etching process can be carried out by using an isotropic wet etching process. Typically, the isotropic wet etching process can be carried out using a solution that contains ammonium. In other cases, the isotropic etching process can be carried out by using an isotropic dry etching process. Typically, the isotropic dry etching process can be carried out using a chemical dry etching (CDE) process.

As shown in FIG. 10A, the second trench portion 100d having the generally round shape has a side portion that contact with the isolation film 171, so as to define fin channel regions 185. The fin channel regions 185 are positioned on opposing sides of the first trench portion 100b. The fin channel region 185 is defined between the generally vertical walls 100a of the first trench portion 100b and the isolation film 171. The fin channel region 185 is separated by the second trench portion 100d from the semiconductor substrate 101. A pair of the fin channel regions 185 is formed in each active region K. Each fin channel region 185 is defined by the first and second trench portions 101b and 101d and the isolation film 171. The lower portion of each fin channel region 185 is tapered between the generally round wall 100c and the isolation film 171. Each fin channel region 185 has a bottom edge 185a which is defined by the generally round wall 100c of the second trench portion 100d. The second trench portion 100d with the generally round wall 100c isolates the fin channel region 185 from a lower portion of the active region K of the semiconductor substrate 101.

### (Process for Forming a Gate Electrode)

With reference to FIGS. 11A and 11B, a gate insulating film 191 may be formed on the generally vertical walls 100a and the generally round wall 100c as well as on the surface of the active region K. The gate insulating film 191 may extend along the generally vertical walls 100a and the generally round wall 100c. Each fin channel region 185 is disposed between the gate insulating film 191 on the generally vertical walls 100a and the isolation film 171. The lower portion of each fin channel region 185 is tapered between the gate insulating film 191 and the isolation film 171. The bottom edge 185a of each fin channel region 185 is defined by the gate insulating film 191 on the generally round wall 100c.

In some cases, the gate insulating film 191 may be formed as follows. The silicon oxide film 181 and the silicon oxide film 111 are removed from the generally vertical walls 100a and the surface of the semiconductor substrate 101, respectively, so that the generally vertical walls 100a and the surface of the semiconductor substrate 101 are exposed. Removal of the silicon oxide film 181 and the silicon oxide film 111 can be carried out by using an HF solution. In some cases, a thermal oxidation process may be carried out to form a silicon oxide film that performs as the gate insulating film 191. Preferably, an In-Situ Stream Generation (ISSG) oxidation method can be used to form the gate insulating film 191, while forming rounded corners or rounded slopes at the periphery of the opening of the first trench portion 100b as shown in FIG. 11A. In some cases, the silicon oxide film performing as the gate insulating film 191 may have a thickness of, but not limited to, 6 nm.

With reference to FIGS. 12A and 12B, a gate electrode 225 is formed on the gate insulating film 191. The gate electrode 225 fills up the trench grooves 100 and the gate electrode 225 further extends over the isolation film 171. The gate insulating film 191 separates the gate electrode 225 from the fin channel regions 185. In some cases, the gate electrode 225 can be realized by a multi-layered structure such as a double-layered structure. In some cases, the gate electrode 225 can be realized by, but not limited to, a stack of a conductive layer 201 and a low resistive film 211. In some cases, the conductive layer 201 may be, but is not limited to, a polysilicon layer 201. In some cases, the low resistive film 211 can be realized by, but not limited to, a multi-layered structure. The multi-layered structure may be a stack of refractory metal layers such as a tungsten nitride layer and a tungsten layer. When the gate electrode 225 is made up by a stack of the polysilicon layer 201, the tungsten nitride layer and the tungsten layer, then the gate electrode 225 can be formed by the following processes.

A phosphorous-doped polysilicon layer 201 is formed entirely over the semiconductor substrate 101, so that the phosphorous-doped polysilicon layer 201 fills up the trench grooves 100 and extends over the active regions K and the isolation film 171. The concentration of the phosphorous-doped polysilicon layer 201 may be, but is not limited to, 1E20/cm³. The thickness of the phosphorous-doped polysilicon layer 201 may be, but is not limited to, 80 nanometers. A tungsten nitride layer can be formed on the phosphorous-doped polysilicon layer 201. The thickness of the tungsten nitride layer may be, but is not limited to, 5 nanometers. A tungsten layer can be formed on the tungsten nitride layer. The thickness of the tungsten layer may be, but is not limited to, 70 nanometers. The stack of the tungsten nitride layer and the tungsten layer makes up the low resistive film 211 which extends over the conductive layer 201. The stack of the conductive layer 201 and the low resistive film 211 makes up the gate electrode 225.

A cap insulating film 221 is formed over the low resistive film 211. In some cases, the cap insulating film 221 can be realized by, but is not limited to, a silicon nitride film. A low pressure chemical vapor deposition method may be used to form the cap insulating film 221 of silicon nitride. The thickness of the cap insulating film 221 may be, but is not limited to, 140 nanometers.

With reference to FIGS. 13A and 13B, the cap insulating film 221 of silicon nitride is then patterned to form a gate trench pattern 14 of silicon nitride on the low resistive film 211. Patterning the cap insulating film 221 of silicon nitride can be made by a lithography process and a dry etching process.

With reference to FIGS. 14A and 14B, the gate trench pattern 14 of silicon nitride is used as a mask to carry out a dry etching process that selectively etch the low resistive film 211 and the phosphorous-doped polysilicon layer 201, thereby defining the patterns of the gate electrodes 225. The gate electrodes 225 are parts of word lines 2.

As a result, the following structure can be obtained. The semiconductor substrate 101 has the active regions K, each of which is surrounded by the isolation region S. In each active region K, a par of trench grooves 100 is formed. Each trench groove 100 includes the first trench portion 100b and the second trench portion 100d. The first trench portion 100b has the generally vertical walls 100a. The second trench portion 100d is positioned under the first trench portion 100b. The second trench portion 100d has the generally round wall 100c. The second trench portions 100d communicate with the first trench portions 100b. The second trench portion 100d has the maximum horizontal dimension that is greater than the horizontal direction of the first trench portion 100b, The first and second trench portions 100b and 100d make up the trench groove 100.

Each active region K has the pair of fin channel regions 185. The paired fin channel regions 185 are positioned on opposing sides of the trench groove 100. Each fin channel region 185 is disposed between the gate insulating film 191 on the side walls of the trench groove 100 and the isolation film 171. The lower portion of each fin channel region 185 is tapered between the gate insulating film 191 on the generally round wall 100c and the isolation film 171. Each fin channel region 185 has the bottom edge 185a which is defined by the generally round wall 100c of the second trench portion 100d. The second trench portion 100d with the generally round wall 100c isolates the fin channel region 185 from the lower portion of the active region K of the semiconductor substrate 101. Each fin channel region 185 is defined by the first and second trench portions 101b and 101d and the isolation film 171. Each fin channel region 185 is separated by the gate insulating film 191 from the gate electrodes 252.

Each trench groove 100 is filled up by the polysilicon layer 201. The low resistive film 211 is formed on the polysilicon layer 201 so that the polysilicon layer 201 and the low resistive film 211 make up the gate electrodes 252 which are covered by the gate trench patterns 14. The gate electrodes 252 is separated by the gate insulating film 191 from the fin channel regions 185.

### (Process for Forming Source and Drain Regions)

Source and drain regions 241 are formed in shallower portions of each active region K. The source and drain regions 241 have the bottoms which are shallower than the bottoms of the second trench portion 100d. One of the source and drain regions 241 is disposed between the first trench portions 100b of the two adjacent trench grooves 100, and the other is disposed between the first trench portion 101b and the isolation film 171. The source and drain regions 241 are connected to the fin channel regions 185. In some cases, the source and drain regions 241 can be formed as follows.

With reference to FIGS. 15A and 15B, a silicon nitride film 231a is formed entirely over the semiconductor substrate 101. In some cases, the silicon nitride film 231a can be formed by, but not limited to, a low pressure chemical vapor deposition method. In some cases, the thickness of the silicon nitride film 231 a may be, but is not limited to, 5 nanometers.

With reference to FIGS. 16A and 16B, a self-aligned contact method is carried out to selectively remove the silicon nitride film 231a, thereby forming side wall insulators 231 and contact holes 235. The side wall insulators 231 extend along the side walls of the gate electrode 225 and the cap layer 221. The contact holes 235 with the side wall insulators 231 are positioned between two adjacent gate electrodes 225 with the side wall insulators 231. The contact holes 235 penetrate the gate insulating film 191. The contact holes 235 reach the semiconductor substrate 101.

With reference to FIGS. 17A and 17B, source and drain regions 241 are selectively formed in each active region K. In some cases, the source and drain regions 241 may be formed by, but not limited to, an ion-implantation process using the gate electrodes 225 and the side wall insulators 231 as masks. In some cases, the ion-implantation process may be carried out under following conditions. Phosphorous ions are implanted into the active region K at a dose of 1E13/cm², and acceleration energy of 60 keV. Further, arsenic ions are implanted into the active region K at a dose of 1E13/cm², and acceleration energy of 30 keV. A heat treatment is carried out to form the source and drain regions 241 in the active region K. In some cases, the heat treatment can be carried out in an inert gas atmosphere at 900° C. for 10 seconds. A typical example of the inert gas atmosphere may be nitrogen atmosphere.

The source and drain regions 241 each have a junction with the semiconductor substrate 101. Namely, the junction is formed at the boundary between the source and drain regions 241 and the semiconductor substrate 101. The boundary or the junction between the source and drain regions 241 and the semiconductor substrate 101 is deeper than the bottom 185a of each fin channel region 185, so that each fin channel region 185 is separate from the semiconductor substrate 101 by the source and drain regions 241. Each fin channel region 185 is surrounded by the gate insulating film 191, the isolation film 171, and the source and drain regions 241. Each fin channel region 185 is electrically connected to the source and drain regions 241. The boundary or the junction between the source and drain regions 241 and the semiconductor substrate 101 is shallower than the bottom of the trench grooves 100.

With reference back to FIGS. 1B and 1C, contact plugs 251 are formed in the contact holes 235. The contact plugs 251 contact with the source and drain regions 241. The contact plugs 251 are connected to the source and drain regions 241. The contact plugs 251 can be formed as follows. A phosphorous-doped polysilicon layer can be formed entirely over the semiconductor substrate 101. The phosphorous-doped polysilicon layer can be formed by using a low pressure chemical vapor deposition method. The phosphorous-doped polysilicon layer may have a doping concentration of 1E20/cm³. The thickness of the phosphorous-doped polysilicon layer may be, but is not limited to, 80 nanometers. A chemical mechanical polishing process can be carried out by using the cap insulating film 221 as a stopper, so as to polish the phosphorous-doped polysilicon layer, thereby forming the contact plugs 251 in the contact holes 235. As a result of the processes described above, the gate trench MOS transistor Tr.

An inter-layer insulator can be formed over the substrate 101 by using the known processes. Bit lines and other interconnections are formed by using the known processes, thereby forming a DRAM. The know processes may include, but are not limited to, processes for forming a film or a layer, lithography processes and dry etching processes.

As described above, the boundary or the junction between the source and drain regions 241 and the semiconductor substrate 101 is deeper than the bottom 185a of each fin channel region 185, so that each fin channel region 185 is separate from the semiconductor substrate 101 by the source and drain regions 241. Each fin channel region 185 is surrounded by the gate insulating film 191, the isolation film 171, and the source and drain regions 241.

The above structure permits substrate floating effect to be efficiently caused in the fin channel regions 185 as the silicon-on-insulator channel, thereby permitting formation of a single transistor DRAM. The physical connection between the source and drain regions 241 and the semiconductor substrate 101 is ensured to permit effective heat radiation, while suppressing self-heat generation effect.

### EXAMPLE 1

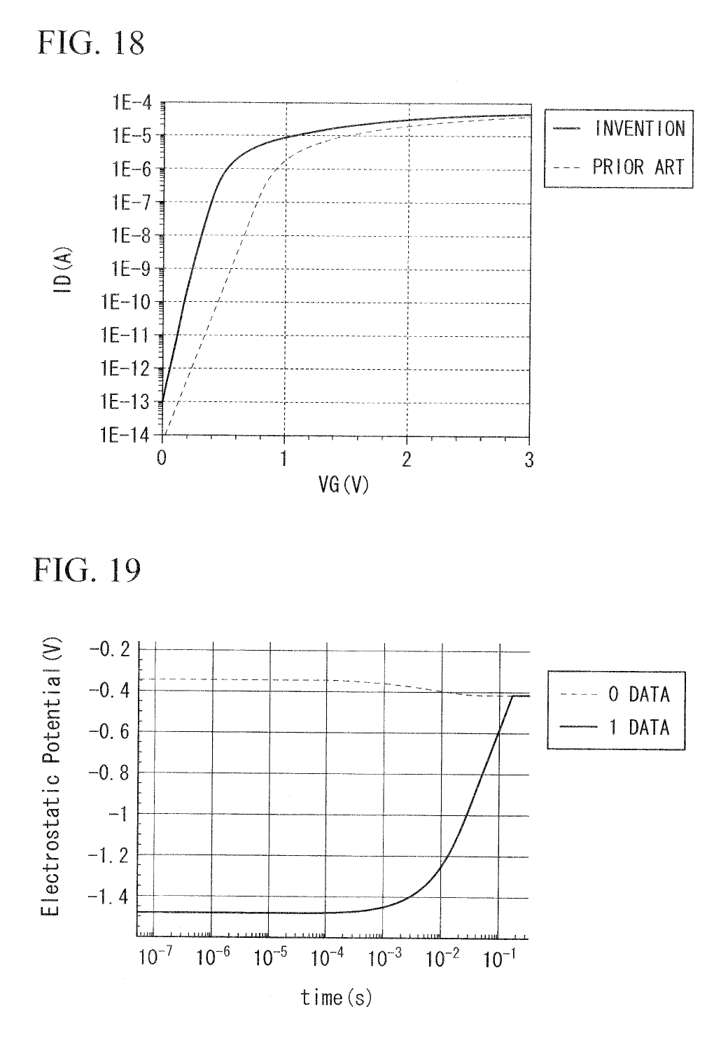

A semiconductor device in accordance with the above-described embodiment was prepared by using the processes described above. The semiconductor device has the structure described above. A bulk substrate semiconductor device is formed by using a bulk substrate in accordance with the known processes. Measured were dependencies of the drain current (ID) upon the gate voltage (VG) of each of the semiconductor device and the bulk substrate semiconductor device. FIG. 18 is a diagram illustrating the measured variations of the drain current (ID) over the gate voltage (VG) of each of the semiconductor device in accordance with the above-described embodiment and the bulk substrate semiconductor device. FIG. 18 is semi-logarithmic coordinate system. The horizontal axis represents the gate voltage VG(V). The vertical axis represents the drain current ID(A). The real line represents the measured variations of the drain current (ID) over the gate voltage (VG) of the semiconductor device in accordance with the above-described embodiment. The broken line represents the measured variations of the drain current (ID) over the gate voltage (VG) of the bulk substrate semiconductor device. FIG. 18 demonstrates that the semiconductor device in accordance with the above-described embodiment is superior more than the bulk substrate semiconductor device in the subthreshold characteristic and the on-current.

### EXAMPLE 2

A simulation was made of transitional characteristics of the substrate floating effect of the semiconductor device in accordance with the embodiment. The semiconductor device may be regarded as a partial depletion device. FIG. 19 is a diagram that illustrates simulated transitional characteristics of the substrate floating effect of the semiconductor device in accordance with the embodiment. FIG. 19 is semi-logarithmic coordinate system. The horizontal axis represents time that is elapsed from operation of writing data “0” or data “1”. The vertical axis represents electrostatic potential. The real line represents the variation of electrostatic potential over time that is elapsed from operation of writing data “1”. The broken line represents the variation of electrostatic potential over time that is elapsed from operation of writing data “0”. When the data “0” is written, a forward bias is applied between the channel and the drain. For example, the drain is biased at −1 V, while the gate electrode is biased at −2 V. The data “1” can be written by an impact ionization process. For example, the drain is biased at +2 V, while the gate electrode is biased at +1.5 V. The above-described structure permits the single transistor DRAM to be operable.

The above-described structure can be applied to a wide variety of semiconductor devices. Typically, the semiconductor device integrates a memory device such as DRAMs, RAMs, ROMs and other semiconductor devices.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments but may be modified and changed without departing from the scope and spirit of the invention.

What is claimed is:

1. A semiconductor device comprising:
a semiconductor substrate that includes an isolation region and at least one active region, the at least one active region having at least one trench groove;
a fin channel region in the at least one active region, the fin channel region being disposed between the at least one trench groove and the isolation region;
a gate insulating film disposed on inside walls of the at least one trench groove;
a gate electrode disposed on the gate insulating film, the gate electrode being disposed in the at least one trench groove, the gate electrode being separated by the gate insulating film from the fin channel region; and
source and drain regions in the at least one active region, the source and drain regions being connected to the fin channel region, the source and drain regions each having a junction with the semiconductor substrate, the junction being deeper than the bottom of the fin channel, region.

2. The semiconductor device according to claim 1, wherein the at least one trench groove comprises:
a first trench portion; and
a second trench portion positioned under the first trench portion, the second trench portion being connected to the first trench portion, the second trench portion separating the bottom of the fin channel region from the semiconductor substrate.

3. The semiconductor device according to claim 2, wherein the fin channel region is defined by the first trench portion, the second trench portion and the isolation region.

4. The semiconductor device according to claim 2, wherein the second trench portion having side portions that contact with the isolation region, so that the bottom of the fin channel region by the side portions from the semiconductor substrate.

5. The semiconductor device according to claim 2, wherein the first trench portion has generally vertical walls, and the second trench portion having a generally round wall that contact with the isolation region, so that the bottom of the fin channel region by the generally round wall from the semiconductor substrate.

6. The semiconductor device according to claim 1, wherein a pair of the fin channel regions are disposed on first opposing sides of the at least one trench groove, and the source and drain regions are disposed on second opposing sides of the at least one trench groove.

7. The semiconductor device according to claim 1, wherein the semiconductor substrate includes an array of the active regions, each active region being surrounded by the isolation region, each active region having a pair of the trench grooves, the gate insulating film and the gate electrode are disposed in each trench groove,
a pair of the fin channel regions are disposed on first opposing sides of each trench groove, and
the source and drain regions are disposed on second opposing sides of each trench groove.

8. A semiconductor device comprising:
a semiconductor substrate that includes an isolation region and at least one active region, the at least one active region having at least one trench groove
a fin channel region in the at least one active region, the fin channel region being disposed between the at least one trench groove and the isolation region, the bottom of the fin channel region being separated from the semiconductor substrate by a portion of the at least one trench groove;
a gate insulating film disposed on inside walls of the at least one trench groove;
a gate electrode disposed on the gate insulating film, the gate electrode being disposed in the at least one trench groove, the gate electrode being separated by the gate insulating film from the fin channel region; and
source and drain regions in the at least one active region, the source and drain regions being connected to the fin channel region.

9. The semiconductor device according to claim 8, wherein the source and drain regions each have a junction with the semiconductor substrate, the junction is deeper than the bottom of the fin channel region.

10. The semiconductor device according to claim 8, wherein the at least one trench groove comprises:
a first trench portion; and
a second trench portion positioned under the first trench portion, the second trench portion being connected to the first trench portion, the second trench portion separating the bottom of the fin channel region from the semiconductor substrate.

11. The semiconductor device according to claim 10, wherein the fin channel region is defined by the first trench portion, the second trench portion and the isolation region.

12. The semiconductor device according to claim 10, wherein the second trench portion having side portions that contact with the isolation region, so that the bottom of the fin channel region by the side portions from the semiconductor substrate.

13. The semiconductor device according to claim 10, wherein the first trench portion has generally vertical walls, and the second trench portion having a generally round wall that contact with the isolation region, so that the bottom of the fin channel region by the generally round wall from the semiconductor substrate.

14. The semiconductor device according to claim 8, wherein a pair of the fin channel regions are disposed on first opposing sides of the at least one trench groove, and the source and drain regions are disposed on second opposing sides of the at least one trench groove.

15. The semiconductor device according to claim 8, wherein the semiconductor substrate includes an array of the active regions, each active region being surrounded by the isolation region, each active region having a pair of the trench grooves,
the gate insulating film and the gate electrode are disposed in each trench groove,
a pair of the fin channel regions are disposed on first opposing sides of each trench groove, and
the source and drain regions are disposed on second opposing sides of each trench groove.

16. A semiconductor device comprising:
a semiconductor substrate that includes an isolation region and at least one active region, the at least one active region having at least one trench groove, the at least one trench groove comprising a first trench portion, and a second trench portion positioned under the first trench portion, the second trench portion being connected to the first trench portion;
a fin channel region in the at least one active region, the fin channel region being disposed between the at least one trench groove and the isolation region, the bottom of the fin channel region being separated from the semiconductor substrate by the second trench portion, and the fin channel region is defined by the first trench portion, the second trench portion and the isolation region;
a gate insulating film disposed on inside walls of the at least one trench groove;
a gate electrode disposed on the gate insulating film, the gate electrode being disposed in the at least one trench groove, the gate electrode being separated by the gate insulating film from the fin channel region; and
source and drain regions in the at least one active region, the source and drain regions being connected to the fin channel region, the source and drain regions each having a junction with the semiconductor substrate, the junction being deeper than the bottom of the fin channel region.

17. The semiconductor device according to claim 16, wherein the second trench portion having side portions that contact with the isolation region, so that the bottom of the fin channel region by the side portions from the semiconductor substrate.

18. The semiconductor device according to claim 16, wherein the first trench portion has generally vertical walls, and the second trench portion having a generally round wall that contact with the isolation region so that the bottom of the fin channel region by the generally round wall from the semiconductor substrate.

19. The semiconductor device according to claim 16, wherein a pair of the fin channel regions are disposed on first opposing sides of the at least one trench groove, and the source and drain regions are disposed on second opposing sides of the at least one trench groove.

20. The semiconductor device according to claim 16, wherein the semiconductor substrate includes an array of the active regions, each active region being surrounded by the isolation region, each active region having a pair of the trench grooves,
the gate insulating film and the gate electrode are disposed in each trench groove,
a pair of the fin channel regions are disposed on first opposing sides of each trench groove, and
the source and drain regions are disposed on second opposing sides of each trench groove.
